(19) United States
(12) Patent Application Publication
(10) Pub. No.: US 2025/0079347 A1
(43) Pub. Date: Mar. 6, 2025

(54) SEMICONDUCTOR DEVICE AND METHOD

(71) Applicant: Huawei Digital Power Technologies Co., Ltd., Shenzhen (CN)

(72) Inventor: Samir Mouhoubi, Nuremberg (DE)

(73) Assignee: Huawei Digital Power Technologies Co., Ltd., Shenzhen (CN)

(21) Appl. No.: 18/953,532

(22) Filed: Nov. 20, 2024

Related U.S. Application Data
(63) Continuation of application No. PCT/EP2022/065971, filed on Jun. 13, 2022.

(51) Int. Cl. H01L 23/62; H01L 23/373; H01L 29/16; H01L 29/20; H01L 29/205; H01L 29/24; H01L 29/267; H01L 29/66; H01L 29/866

(52) U.S. Cl. CPC H01L 23/62; H10D 8/045; H10D 8/25; H01L 23/373; H10D 62/80; H10D 62/82; H10D 62/824; H10D 62/8303; H10D 62/8325; H10D 62/8503

(57) ABSTRACT

A semiconductor device includes: a substrate including a first wide-bandgap semiconductor material; a first region of a first conductivity type and a second region of a second conductivity type arranged above the substrate, where the first region and the second region include a second wide-bandgap semiconductor material, and where the first region and the second region form a Zener PN diode configured as an anti-fuse.

### CROSS-REFERENCE TO RELATED APPLICATIONS

This application is a continuation of International Application No. PCT/EP2022/065971, filed on Jun. 13, 2022, the disclosure of which is hereby incorporated by reference in its entirety.

### FIELD

The present disclosure relates to a semiconductor device. The present disclosure further relates to a method for producing such a semiconductor device.

### BACKGROUND

Anti-fuses are semiconductor electrical devices that have initially a high resistance. After a special treatment referred to as programming, they become low resistive, performing the opposite function to fuses. Anti-fuses are widely used in integrated circuits as programmable logic devices (for design customization), one time programmable read-only memories (OTP), trimming the values of analog components, tuning for voltage reference circuits, or serial code identification for dies and chips (traceability).

One of the most efficient and cost effective anti-fuses developed in silicon-based technologies is the Zener anti-fuse, also named Zener zap. It is present in bipolar technologies, complementary metal oxide semiconductor (CMOS), bipolar CMOS (Bi-CMOS), mixed signal, and smart power technologies.

A Zener device, or generally speaking a PN junction or a Zener diode, is formed by at least two semiconductor elements of opposite conductivity type (different doping elements). One element is of N-type, meaning that it is doped such that it can provide an excess of negative charge (electrons), whereas the other element is of P-type and is doped such that it can provide an excess of positive charge (holes).

A Zener anti-fuse is programmed by applying to a Zener diode either a high voltage or a high current over a short time duration. The voltage spike or the current spike causes enough energy to overheat the structure and permanently damage it, thereby shorting it out. The programming through current spikes (or voltage spikes) is called Zener zapping. The Zener zapping is schematically depicted in FIG. 1.

Wide-bandgap (WBG) technologies are new technologies being developed to replace silicon technologies. Their superior material properties compared to silicon make them more suitable for various applications and domains, such as power applications.

Zener anti-fuses are currently not used in WBG semiconductor technologies due to several reasons including for example:
a) The level of maturity: WBG technologies are still under research and development and less ready for integration to existing technologies, except for gallium nitride (GaN), for example.
b) Many topologies adopted in WBG are vertical, which could lead to difficulties to integrate devices.

Currently there are no known implementations of Zener anti-fuses in WBG technologies. Lately academia and industry are focusing on the integration of basic elements and circuitry around a power GaN High Electron Mobility Transistor (HEMT).

The natural solution that the industry may adopt can be to co-integrate GaN HEMT power devices with silicon-based anti-fuses. However, this means encapsulating in one package two different dies from two different technologies. This solution may require a complex packaging scheme, especially regarding the placing and wiring/connecting the different dies. In addition, the reliability of the entire co-packaged system may not be ensured, and the resulting chip area may increase due to usage of two dies.

### SUMMARY

Aspects of the present disclosure improve the above-mentioned implementations by integrating a Zener anti-fuse monolithically in WBG technology.

According to a first aspect, a semiconductor device is provided, which includes: a substrate including a first wide-bandgap semiconductor material; a first region of a first conductivity type and a second region of a second conductivity type arranged above the substrate, where the first region and the second region include a second WBG semiconductor material, and where the first region and the second region form a Zener PN diode configured as an anti-fuse.

The WBG semiconductor material includes a material with a bandgap in the range above 2 eV.

According to the first aspect a Zener anti-fuse can be monolithically integrated in WBG technology.

In an implementation form of the first aspect, the first region and the second region are arranged in a horizontal configuration with respect to their arrangement above the substrate, where the first region is arranged above the substrate and the second region is arranged above the substrate and next to the first region. Alternatively, the first region and the second region are arranged in a vertical configuration with respect to their arrangement above the substrate, where the second region is arranged above the first region and the first region is arranged above the substrate.

This provides the advantage that the Zener anti-fuse can be easily integrated in both horizontal and vertical WBG technologies.

In an implementation form of the first aspect, the first region and the second region are separated by a distance. Alternatively, the first region and the second region are contiguous. Alternatively, the first region and the second region are partially overlapping.

This provides the advantage that the efficiency of the programming or zapping process can be optimized in terms of time, voltage applied, current applied and/or energy dissipated.

In an implementation form of the first aspect, the first region has a first shape including a first lateral protrusion. The first lateral protrusion has a tip shape or a truncated tip shape or another polygon shape, or the first shape includes a cylindrical shape or a cylindrical shape with a first lateral protrusion, where the first lateral protrusion has a tip shape or a truncated tip shape or another polygon shape. Additionally, the second region has a second shape, including a second lateral protrusion. The second lateral protrusion has a tip shape or a truncated tip shape or another polygon shape, or the second shape includes a cylindrical shape or a cylindrical shape with a second lateral protrusion, where the lateral protrusion has a tip shape or a truncated tip shape or another polygon shape.

This may further optimize the efficiency of the programming or zapping process in terms of time, voltage applied, current applied and/or energy dissipated.

In an implementation form of the first aspect, the semiconductor device further includes a first metallic gate in electrical contact with the first region, and a second metallic gate in electrical contact with the second region.

This provides the advantage that a metallic filament may be formed between the first region of the first conductivity type and the second region of the second conductivity type, to cause an electrical short and, thus, enable programming of the Zener PN junction configured as an anti-fuse.

In an implementation form of the first aspect, the semiconductor device further includes a semiconductor layer including a third wide-bandgap semiconductor material. The semiconductor layer is arranged between the substrate and the first region and the second region, respectively.

This provides the advantage that a channel is formed below the semiconductor layer in a region under the first region and the second region, enabling the implementation of a Zener anti-fuse in HEMT technologies.

In an implementation form of the first aspect, the semiconductor device further includes a semiconductor layer including a third wide-bandgap semiconductor material, where the semiconductor layer is arranged above the first region and the second region, or where the second region is arranged above the first region, and the semiconductor layer is arranged above the second region.

This provides the advantage that a channel is formed in a region above the first region and the second region, enabling the implementation of a Zener anti-fuse in vertical HEMT technologies.

In an implementation form of the first aspect, the first metallic gate and the second metallic gate contact the first region and the second region through the semiconductor layer. Alternatively, the second metallic gate contacts the second region through the semiconductor layer.

In an implementation form of the first aspect, the semiconductor device further includes: at least one additional first region of the first conductivity type and at least one additional second region of the second conductivity type that are arranged above the semiconductor layer, where the at least one additional first region and the at least one additional second region include the second wide-bandgap semiconductor material; at least one additional first metallic gate in electrical contact with the at least one additional first region and at least one additional second metallic gate in electrical contact with the at least one additional second region; and at least one additional semiconductor layer including the third wide-bandgap semiconductor material and arranged above the at least one additional first region and the at least one additional second region; where the at least one additional first metallic gate and the at least one additional second metallic gate contact the at least one additional first region and the at least one additional second region through the at least one additional semiconductor layer, and where the at least one additional first region and the at least one additional second region form at least one additional Zener PN diode configured as an anti-fuse.

This provides the advantage that a multi-stack of Zener anti-fuses in WBG technologies can be created.

In an implementation form of the first aspect, the first region and the second region are arranged in an N-well structure or a P-well structure formed in the substrate. Alternatively, the first region is arranged in a first well structure and the second region is arranged in a second well structure, where the first well structure and the second well structure include an N-well structure or a P-well structure formed in the substrate.

This provides the advantage that Zener anti-fuses can be integrated in WBG and ultra-wide bandgap (UWBG) technologies.

In this disclosure, an UWBG semiconductor material comprises a semiconductor material with a bandgap above 4 eV.

In an implementation form of the first aspect, the semiconductor device further includes at least one structure of a thermal insulation material that is partially or fully in contact with the first region, additionally or alternatively with the second region, additionally or alternatively with the substrate, where the at least one structure of thermal insulation material includes silicon dioxide (SiO₂), or a nitride compound including any one of silicon nitride (Si₃N₄), or aluminum gallium nitride (AlGaN), or aluminum nitride (AlN).

This provides the advantage of causing a thermal enhancement, e.g. overheating, during a zapping process that may facilitate the programming of the Zener PN diode configured as an anti-fuse.

In an implementation form of the first aspect, the semiconductor device further includes an intermediate region of a third conductivity type that is arranged between the first region and the second region, where the intermediate region includes the second wide-bandgap semiconductor material, and where the intermediate region is a P-type region or an N-type region or an undoped-type region.

This provides the advantage of further facilitating a programming or zapping process of the Zener PN diode configured as an anti-fuse.

In an implementation form of the first aspect, the second wide-bandgap semiconductor material includes GaN.

In an implementation form of the first aspect, the third wide-bandgap material includes AlGaN.

In an implementation form of the first aspect, the first metallic gate is partially or totally in contact with the first region. Alternatively, the first metallic gate extends partially or totally inside the first region. The second metallic gate is partially or totally in contact with the second region, or the second metallic gate extends partially or totally inside the second region.

In an implementation form of the first aspect, the first metallic gate and the second metallic gate include aluminum, titanium, copper, gold or another metallic element, or a metal stack including any one of nickel/gold (Ni/Au), nickel/silver (Ni/Ag), Palladium/gold (Pd/Au), Chromium/gold (Cr/Au), Platinum/gold (Pt/Au), Titanium/Platinum/gold (Ti/Pt/Au), nickel/silicone (Ni/Si), Tungsten/silicone (W/Si), Titanium/Aluminum (Ti/Al), Titanium/Aluminum/Titanium (Ti/Al/Ti), or Titanium nitride/Aluminum/Titanium nitride (TiN/Al/TiN).

In an implementation form of the first aspect, the first wide-bandgap semiconductor material includes silicon carbide (SiC), or gallium oxide (Ga₂O₃). Alternatively, the first wide-bandgap semiconductor material includes a heteroepitaxial bulk material, where the heteroepitaxial bulk material includes gallium nitride, GaN, on silicon, Si, or GaN on SiC, or GaN on diamond, or a wide-bandgap semiconductor on insulator material.

According to a second aspect, a method for producing a semiconductor device is provided. The method includes: providing a substrate including a first wide-bandgap semiconductor material; forming a first region of a first conductivity type and a second region of a second conductivity type arranged above the substrate, where the first region and the second region include a second wide-bandgap semiconductor material, and where the first region and the second region form a Zener PN diode configured as an anti-fuse.

The wide-bandgap semiconductor material comprises a material with a bandgap in the range above 2 eV.

This provides the advantage of providing a Zener anti-fuse that can be monolithically integrated in a WBG technology.

In an implementation form of the second aspect, the first region and the second region are arranged in a horizontal configuration with respect to their arrangement above the substrate, where the first region is arranged above the substrate and the second region is arranged above the substrate and next to the first region. Alternatively, the first region and the second region are arranged in a vertical configuration with respect to their arrangement above the substrate, where the second region is arranged above the first region and the first region is arranged above the substrate.

This provides the advantage that the Zener anti-fuse can be easily integrated in both horizontal and vertical WBG technologies.

In an implementation form of the second aspect, the first region and the second region are separated by a distance. Alternatively, the first region and the second region are contiguous. Alternatively, the first region and the second region are partially overlapping.

This provides the advantage that efficiency of the programming or zapping process can be optimized in terms of time, voltage applied, current applied and/or energy dissipated.

In an implementation form of the second aspect, the first region has a first shape including a first lateral protrusion. The first lateral protrusion has a tip shape or a truncated tip shape or another polygon shape, or the first shape includes a cylindrical shape or a cylindrical shape with a first lateral protrusion, where the first lateral protrusion has a tip shape or a truncated tip shape or another polygon shape. Additionally, the second region has a second shape, including a second lateral protrusion. The second lateral protrusion has a tip shape or a truncated tip shape or another polygon shape, or the second shape includes a cylindrical shape or a cylindrical shape with a second lateral protrusion, where the lateral protrusion has a tip shape or a truncated tip shape or another polygon shape.

This may further optimize the efficiency of the programming or zapping process in terms of time, voltage applied, current applied and/or energy dissipated.

In an implementation form of the second aspect, the method further includes forming a first metallic gate in electrical contact with the first region, and a second metallic gate in electrical contact with the second region.

This provides the advantage that a metallic filament may be formed between the first region of the first conductivity type and the second region of the second conductivity type to cause an electrical short and, thus, enabling programming of the Zener PN junction configured as an anti-fuse.

In an implementation form of the second aspect, the method further includes a semiconductor layer including a third wide-bandgap semiconductor material that is arranged between the substrate and the first region and the second region, respectively.

This provides the advantage that a channel is formed below the semiconductor layer in a region under the first region and the second region, enabling the implementation of a Zener anti-fuse in HEMT technologies.

In an implementation form of the second aspect, the method further includes forming a semiconductor layer including a third wide-bandgap semiconductor material, where the semiconductor layer is arranged above the first region and the second region, or where the second region is arranged above the first region, and the semiconductor layer is arranged above the second region.

This provides the advantage that a channel is formed in a region above the first region and the second region, enabling the implementation of a Zener anti-fuse in vertical HEMT technologies.

In an implementation form of the second aspect, the first metallic gate and the second metallic gate contact the first region and the second region through the semiconductor layer. Alternatively, the second metallic gate contacts the second region through the semiconductor layer.

In an implementation form of the second aspect, the method further includes: forming at least one additional first region of the first conductivity type and at least one additional second region of the second conductivity type that are arranged above the semiconductor layer, where the at least one additional first region and the at least one additional second region include the second wide-bandgap semiconductor material; forming at least one additional first metallic gate in electrical contact with the at least one additional first region and at least one additional second metallic gate in electrical contact with the at least one additional second region; and forming at least one additional semiconductor layer including the third wide-bandgap semiconductor material and arranged above the at least one additional first region and the at least one additional second region; where the at least one additional first metallic gate and the at least one additional second metallic gate contact the at least one additional first region and the at least one additional second region through the at least one additional semiconductor layer, and where the at least one additional first region and the at least one additional second region form at least one additional Zener PN diode configured as an anti-fuse.

This provides the advantage that a multi-stack of Zener anti-fuses in WBG technologies can be created.

In an implementation form of the second aspect, the first region and the second region are arranged in an N-well structure or a P-well structure formed in the substrate. Alternatively, the first region is arranged in a first well structure and the second region is arranged in a second well structure, where the first well structure and the second well structure include an N-well structure or a P-well structure formed in the substrate.

This provides the advantage that Zener anti-fuses can be integrated in WBG and UWBG technologies.

In this disclosure, an UWBG semiconductor material comprises a semiconductor material with a bandgap above 4 eV.

In an implementation form of the second aspect, the method further includes forming at least one structure of a thermal insulation material that is partially or fully in contact with the first region, additionally or alternatively with the second region, additionally or alternatively with the substrate, where the at least one structure of thermal insulation material includes SiO₂, or a nitride compound including any one of Si₃N₄, or AlGaN, or AlN.

This provides the advantage of causing a thermal enhancement, e.g., overheating, during a zapping process that may facilitate the programming of the Zener PN diode configured as an anti-fuse.

In an implementation form of the second aspect, the method further includes an intermediate region of a third conductivity type that is arranged between the first region and the second region, where the intermediate region includes the second wide-bandgap semiconductor material, and where the intermediate region is a P-type region or an N-type region or an undoped-type region.

This provides the advantage of further facilitating a programming or zapping process of the Zener PN diode configured as an anti-fuse.

In an implementation form of the second aspect, the second wide-bandgap semiconductor material includes GaN.

In an implementation form of the second aspect, the third wide-bandgap material includes AlGaN.

In an implementation form of the second aspect, the first metallic gate is partially or totally in contact with the first region. Alternatively, the first metallic gate extends partially or totally inside the first region. The second metallic gate is partially or totally in contact with the second region, or the second metallic gate extends partially or totally inside the second region.

In an implementation form of the first aspect, the first metallic gate and the second metallic gate include aluminum, titanium, copper, gold or another metallic element, or a metal stack including any one of Ni/Au, Ni/Ag, Pd/Au, Cr/Au, Pt/Au, Ti/Pt/Au, Ni/Si, W/Si, Ti/Al, Ti/Al/Ti, or TiN/Al/TiN.

In an implementation form of the second aspect, the first wide-bandgap semiconductor material includes SiC or Ga₂O₃. Alternatively, the first wide-bandgap semiconductor material includes a heteroepitaxial bulk material, where the heteroepitaxial bulk material includes GaN on Si, or GaN on SiC, or GaN on diamond, or a wide-bandgap semiconductor on insulator material.

The method according to the second aspect and its implementation forms provide the same advantages and effects as described above for the device of the first aspect and its respective implementation forms.

### BRIEF DESCRIPTION OF DRAWINGS

The above described aspects and implementation forms of the present disclosure will be explained in the following description in relation to the enclosed drawings, in which:

FIG. 1 generally depicts the Zener zapping process;

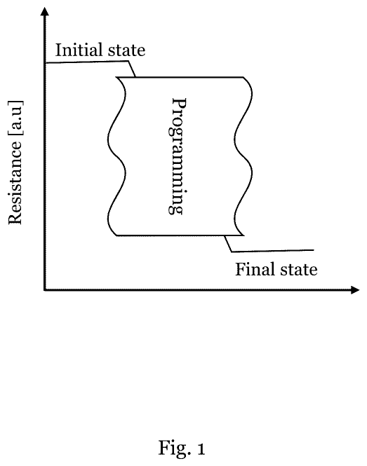

FIG. 2 shows a schematic diagram of a semiconductor device according to the present disclosure;

FIGS. 3a-d show top view of examples of the first shape and the second shape according to the present disclosure;

FIG. 4 shows a schematic diagram of a semiconductor device according to the present disclosure;

FIGS. 5a-c show schematic diagrams of examples of a metallic gate in a semiconductor device according to the present disclosure;

FIGS. 6a-b show schematic diagrams of examples of a metallic gate in a semiconductor device according to the present disclosure;

FIG. 7 shows a schematic diagram of a semiconductor device according to the present disclosure;

FIGS. 8a-c show schematic diagrams of a semiconductor device according to the present disclosure;

FIGS. 9a-b show schematic diagrams of a semiconductor device according to the present disclosure;

FIG. 10 shows a schematic diagram of a semiconductor device according to the present disclosure;

FIG. 11 shows a schematic diagram of a semiconductor device according to the present disclosure;

FIG. 12 shows a schematic diagram of a semiconductor device according to the present disclosure; and

FIG. 13 shows a method for producing a semiconductor device according to the present disclosure.

### DETAILED DESCRIPTION

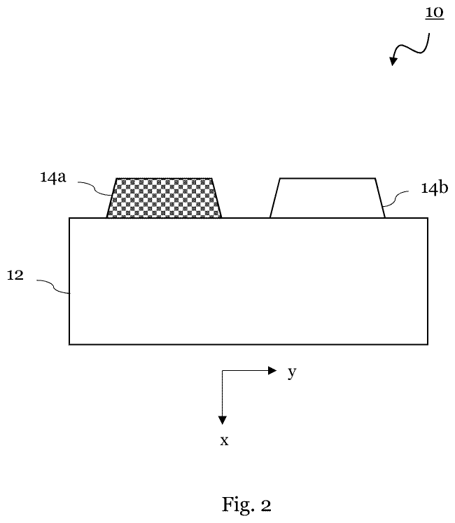

FIG. 2 shows a schematic diagram of a semiconductor device 10 according to an exemplary embodiment of the present disclosure. The semiconductor device 10 includes a substrate 12, a first region 14a of a first conductivity type and a second region 14b of a second conductivity type 14b. The first region 14a and the second region 14b are arranged above the substrate 12.

The substrate 12 includes a first WBG semiconductor material, comprising SiC or Ga₂O₃. Alternatively, the first WBG semiconductor material includes a heteroepitaxial bulk material. Said heteroepitaxial bulk material includes GaN on silicon (Si), or GaN on SiC, or GaN on diamond, or a WBG semiconductor on insulator material. The substrate 12 may include a base structure with one or more layers on top formed by an epitaxial growth process.

The first region 14a and the second region 14b include a second WBG semiconductor material. The second WBG semiconductor material includes GaN.

Conventional semiconductors like e.g., silicon, have a bandgap in the range of 0.6-1.5 eV, whereas WBG materials have a bandgap in the range above 2 eV. Such a larger band gap enables devices based on WBG semiconductors to operate at higher voltages, frequencies, and temperatures than those based on conventional semiconductor materials.

In this disclosure, a WBG semiconductor material includes a semiconductor material with a bandgap in the range above 2 eV.

For example, the band gap value of GaN is 3.44 eV.

The first region 14a of a first conductivity type may be a P-type region or an N-type region. Conversely, the second region 14b of the second conductivity type may be an N-type region or a P-type region. Thus, the first region 14a and the second region 14b form a Zener PN diode configured as an anti-fuse.

In general, the semiconductor device 10 can be manufactured by standard mask/implant processes, controlled successive epitaxial growths and successive epitaxy and etching techniques.

The first region 14a of the first conductivity type and the second region 14b of the second conductivity type may be fabricated by conventional techniques for WBG technologies, for example, from undoped GaN by implantation, in-situ or ex-situ incorporation of dopants during epitaxial growth, metalorganic chemical vapor deposition (MOCVD) growth, molecular-beam epitaxy (MBE), delta doping or other deposition/doping techniques.

Alternatively, the first region 14a of the first conductivity type and the second region 14b of the second conductivity can be created by successive epitaxial growths combined with selective etchings and regrowth, thereby enabling a fine-tuning of the dopant profile in each region 14a and 14b.

The chemical species used for doping the first region 14a and the second region 14b may be for example, but not as a limitation, magnesium, iron or silicon.

The design of Zener anti-fuses relies on the creation of intentional abrupt geometrical layout changes in the two regions 14a and 14b with different conductivity types to enhance an electric field and cause an early destruction of the PN diode. The choice of a geometrical shape and a doping level can be made to optimize the efficiency of the programming process in terms of time, voltage applied, current applied and/or energy dissipated.

Thus, in this disclosure, the first region 14a of the first conductivity type has a first shape and the second region 14b of the second conductivity type has a second shape, which may optimize the efficiency of the programming or zapping process.

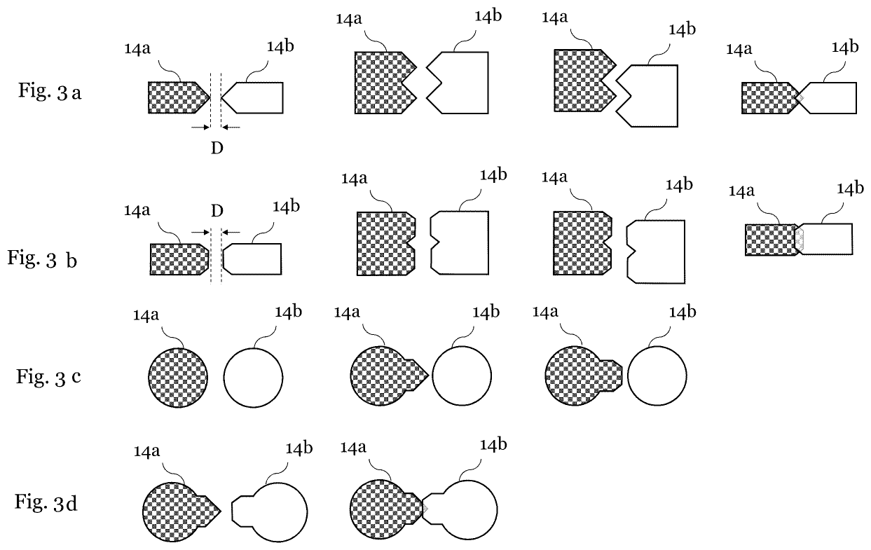

FIGS. 3a to 3d show a top view of different examples of the first shape of the first region 14a and the second shape of the second region 14b. The first region 14a may have a first shape including a first lateral protrusion. Said first lateral protrusion may have a tip shape, see FIG. 3a, or a truncated tip shape, see FIG. 3b, or another polygon shape. Alternatively, the first shape may include a cylindrical shape (e.g., the circular shape shown in the top view in FIG. 3c), or a cylindrical shape having a first lateral protrusion, where the first lateral protrusion has a tip shape or a truncated tip shape or another polygon shape, see FIGS. 3c and 3d.

The second region 14b may have a second shape including a second lateral protrusion. The second lateral protrusion may have a tip shape, see FIG. 3a, or a truncated tip shape, see FIG. 3b, or another polygon shape, or the second shape includes a cylindrical shape, see FIG. 3c, or a cylindrical shape with a second lateral protrusion, wherein the lateral protrusion has a tip shape or a truncated tip shape or another polygon shape (see FIGS. 3c and 3d).

The first shape of the first region 14a and the second shape of the second region 14b can be the same or can be different from each other.

Further, the first region 14a and the second region 14b may be separated by a distance, depicted as the distance D in the first column (from left to right) of FIGS. 3a and 3b. Alternatively, the first region 14a and the second region 14b may be contiguous. Alternatively, the first region 14a and the second region 14b may be partially overlapping, as shown for example in the fourth column in FIGS. 3a and 3b.

The first lateral protrusion of the first region 14a and the second lateral protrusion of the second region 14b may be aligned, as depicted for example in the first, second and fourth columns in FIGS. 3a and 3b.

A layout in which the first shape of the first region 14a has a first lateral protrusion having a tip shape and the second shape of the second region 14a has a second lateral protrusion having a tip shape, as shown for Example in FIG. 3a, may allow the most energy efficient programming process, and can be separated by a distance or can be contiguous or can partially overlap.

In a layout in which the first shape of the first region 14a has a first lateral protrusion having a truncated tip shape or another polygon shape and the second shape of the second region 14a has a second lateral protrusion having a truncated tip shape or another polygon shape, as shown for Example in FIG. 3b, the energy needed to program the Zener anti-fuse can be adjusted to fulfill specific technological requirements.

The fabrication of the first region 14a and the second region 14b as well as the first shape of the first region 14a and the second shape of the second region 14b can be controlled by a combination of epitaxy, etching and implantation processes.

A thickness of the first region 14a and a thickness of the second region 14b can be tuned in order to achieve an efficient zapping process.

In the embodiment shown in FIG. 2, the first region 14a and the second region 14b are arranged in a horizontal configuration with respect to their arrangement above the substrate 12. Thereby, the first region 14a is arranged above the substrate 12 and the second region 14b is arranged above the substrate 12 and next to the first region 14a.

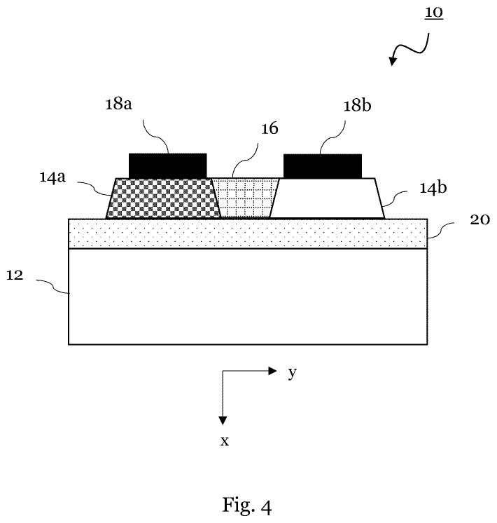

In an exemplary embodiment, shown in FIG. 4, the semiconductor device 10 further includes an intermediate region 16 of a third conductivity type that is arranged between the first region 14a and the second region 14b. The intermediate region 16 includes the second wide-bandgap semiconductor material, and the intermediate region 16 is a P-type region or an N-type region. Alternatively, the intermediate region 16 is an undoped-type region.

A thickness of the first region 14a, a thickness of the second region 14b and a thickness of the intermediate region 16 can be tuned in order to achieve an efficient zapping process. Further, similar to the first region 14a and the second region 14b, the intermediate region 16 of the third conductivity type may be fabricated by conventional techniques for WBG technologies.

In the exemplary embodiment depicted in FIG. 4, the semiconductor device 10 further includes a semiconductor layer 20 that is arranged between the substrate 12 and the first region 14a and the second region 14b, respectively. The semiconductor layer 20 includes a third WBG semiconductor material. For example, the third WBG semiconductor material includes AlGaN, and has a band gap value of about 6 eV.

In the exemplary embodiment depicted in FIG. 4, the semiconductor layer 20 provides a two-dimensional electron gas (2DEG) at the AlGaN/GaN interface below the first region 14a and the second region 14b, e.g., below the Zener PN diode configured as an anti-fuse, which can be adjusted by further providing an isolation implantation.

The first region 14a of the first conductivity type, the second region 14b of the second conductivity type and the intermediate region 16 of the third conductivity type can be epitaxially grown on the semiconductor layer 20. Alternatively, the first region 14a of the first conductivity type, the second region 14b of the second conductivity type and intermediate region 16 of the third conductivity type may be grown on an area not containing the semiconductor layer 20, for example after partial or total etching of the semiconductor layer 20.

The semiconductor device 10 may further comprise a first metallic gate 18a that may be in electrical contact with the first region 14a, and a second metallic gate 18b that may be in electrical contact with the second region 14b. The first metallic gate 18a and the second metallic gate 18b may include aluminum, titanium, copper, gold or another metallic element. Alternatively, the first metallic gate 18a and the second metallic gate 18b may include a metal stack comprising any one of Ni/Au, Ni/Ag, Pd/Au, Cr/Au, Pt/Au, Ti/Pt/Au, Ni/Si, W/Si, Ti/Al, Ti/Al/Ti, or TiN/Al/TiN. However, other suitable material combinations may also be possible.

The first metallic gate 18a may be partially or totally in contact with the first region 14a. Alternatively, the first metallic gate 18a may extend partially or totally inside the first region 14a. The second metallic gate 18b may be partially or totally in contact with the second region 14b. Alternatively, the second metallic gate 18b may extend partially or totally inside the second region 14b.

In some instances, the first metallic gate 18a or the second metallic gate 18b may be partially or totally in contact with the intermediate region 16.

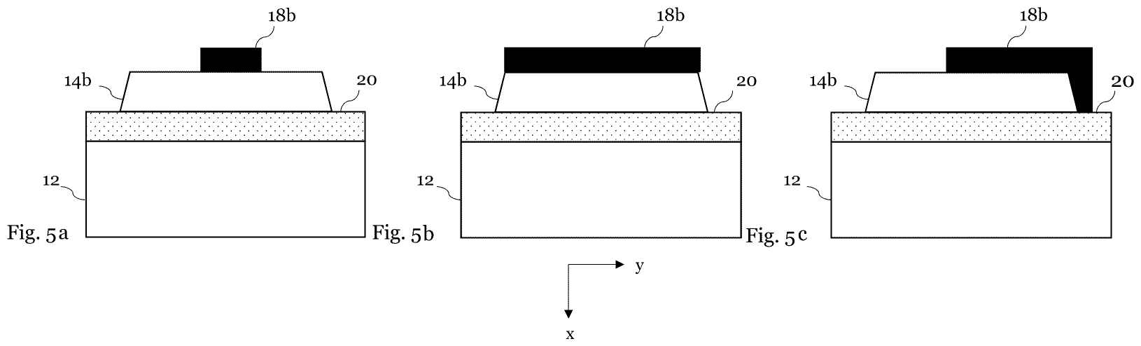

FIGS. 5a to 5c show schematic diagrams of examples of a metallic gate in a semiconductor device 10, where only the second region 14b of the second conductivity type, the second metallic gate 18b, a part of the semiconductor layer 20 below the second region 14b and a part of the substrate 12 below the semiconductor layer 20 are shown for the sake of clarity. In the examples shown in FIGS. 5a and 5c, the second metallic gate 18b is partially in contact with the second region 14b, whereas the example of FIG. 5b depicts the second metallic gate 18b fully in contact with the second region 14b.

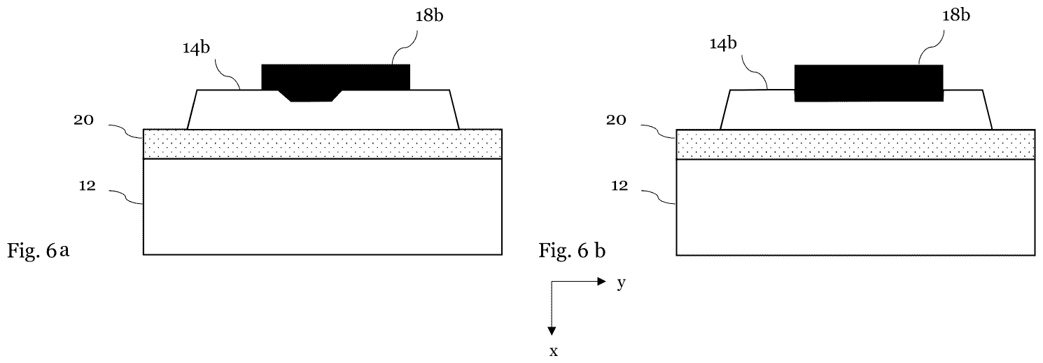

FIGS. 6a and 6b show schematic diagrams of examples of a metallic gate in the semiconductor device 10, where only the second region 14b of the second conductivity type, the second metallic gate 18b, a part of the semiconductor layer 20 below the second region 14b and a part of the substrate 12 below the semiconductor layer 20 are shown for the sake of clarity. In the example shown in FIG. 6a, the second metallic gate 18b extends partially inside the second region 14b, e.g., a portion of a width of the second metallic gate 18b extends inside the second region 14b. In the example shown in FIG. 6b, the second metallic gate 18b extends totally inside the second region 14b, e.g., the complete width of the second metallic gate 18b extends inside the second region 14b.

The first metallic gate 18a and the second metallic gate 18b may be fabricated by standard deposition/sputtering/filling/etching of metallic elements on a surface of the first region 14a and the second region 14b, respectively. The first metallic gate 18a and the second metallic gate 18b may be easily fabricated, for example, during the manufacture of a wafer. Alternatively, the first metallic gate 18a and the second metallic gate 18b may be fabricated by metal deposition/sputtering/filling of a wafer backside etched areas. Alternatively, the first metallic gate 18a and the second metallic gate 18b may be fabricated by a combination of both fabrication techniques.

An electrical separation (isolation) of the first metallic gate 18a and the second metallic gate 18b may be provided. This can be achieved by providing a regular spacing between the first metallic gate 18a and the second metallic gate 18b filled with dielectric materials.

The semiconductor device 10 of the embodiment shown in FIG. 4 can be a HEMT device in which a Zener anti-fuse is integrated and, thus, conventional fabrication techniques of HEMT technologies may be used to produce the semiconductor device 10.

The embodiment shown in FIG. 4 may enable a relatively simple implementation of a Zener anti-fuse, since no deviations from the standard HEMT technology and process flow are required. Moreover, since the first region 14a of a first conductivity type and the second region 14b of the second conductivity type can be formed by regular mask/implant processes of an undoped GaN material, embodiments of the present disclosure provide with a cost-effective implementation of the semiconductor device 10. Alternatively, since the first region 14a of a first conductivity type and the second region 14b of the second conductivity can be created by successive epitaxial growths combined with selective etchings and regrowth, embodiments of the present disclosure may achieve an optimal performance of the Zener PN diode configured as an anti-fuse; however, in this example the manufacturing cost and complexity may increase.

In an exemplary embodiment, the first region 14a of the first conductivity type and the second region 14b of the second conductivity type are arranged in a vertical configuration with respect to their arrangement above the substrate 12. The vertical configuration may comprise a full vertical configuration or a semi-vertical configuration.

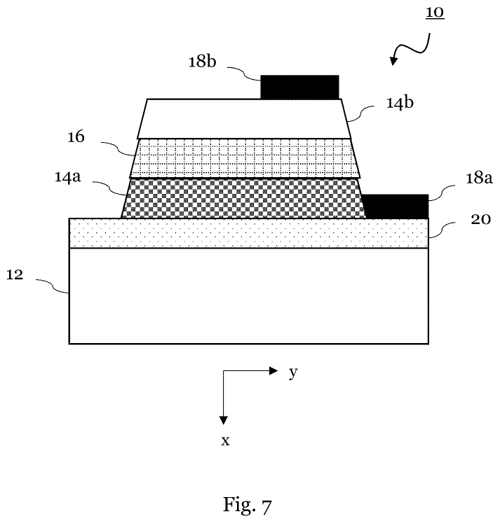

FIG. 7 shows a schematic diagram of a semiconductor device 10 where the first region 14a of the first conductivity type and the second region 14b of the second conductivity type are arranged in a full vertical configuration. In this embodiment, the second region 14b is arranged above the first region 14a, and the first region 14a is arranged above the substrate 12. The semiconductor device 10 may further include the intermediate region 16 of the third conductivity type that is arranged between the first region 14a and the second region 14b, and the semiconductor layer 20 that is arranged between the substrate 12 and the first region 14a and the second region 14b.

As in the previous exemplary embodiments and examples, the substrate 12 includes the first WBG semiconductor material; the first region 14a of the first conductivity type, the second region 14b of the second conductivity type and the intermediate region 16 include the second WBG semiconductor material; and the semiconductor layer 20 includes the third WBG semiconductor material.

In the exemplary embodiment shown in FIG. 7, the semiconductor device 10 further includes the first metallic gate 18a in electrical contact with the first region 14a, and the second metallic gate 18b in electrical contact with the second region 14b.

The first metallic gate 18a may be partially or totally in contact with the first region 14a, or the first metallic gate 18a extends partially or totally inside the first region 14a. The second metallic gate 18b may be partially or totally in contact with the second region 14b, or the second metallic gate 18b extends partially or totally inside the second region 14b, as in the examples shown in FIGS. 5a to 5c or 6a to 6b. The first metallic gate 18a or the second metallic gate 18b may partially extend inside the intermediate region 16. The first metallic gate 18a and the second metallic gate 18b include the same materials as disclosed in the previous embodiments and examples.

In the exemplary embodiment of FIG. 7, the fabrication of the first region 14a and the second region 14b as well as the first shape of the first region 14a and the second shape of the second region 14b can be achieved by etching of the first region 14a, of the second region 14b and/or of the intermediate region 16, including for example masked bevel etching, creating sharp corners in the first region 14a, in the second region 14b and/or in the intermediate region 16, respectively, achieving the desired first shape and second shape that may enhance the zapping process.

Alternatively, after growing the first region 14a, a wafer can be taken out of a MOCVD reactor to perform a masked etching. Then, the wafer may be brought back to the MOCVD reactor to grow the intermediate region 16 and, optionally, the wafer can be subsequently taken out of the MOCVD reactor to perform another masked etching. Then, the wafer may be brought back to the MOCVD reactor to grow the second region 14b, and the wafer can be subsequently taken out of the MOCVD reactor to perform a masked etching. At the etched areas of the first region 14a and the second region 14b, sharp corners may be formed, achieving the desired first shape and second shape that may enhance the zapping process.

The semiconductor device 10 of the embodiment shown in FIG. 7 can be a HEMT device in which a Zener anti-fuse is integrated and, thus, conventional fabrication techniques of HEMT technologies may be used to produce the semiconductor device 10.

The embodiment of FIG. 7 may allow the combination of layers growth in a MOCVD reactor, which decreases the manufacturing cost. Furthermore, due to the vertical configuration, it may allow the integration of the Zener PN diode configured as an anti-fuse into HEMT devices having both horizontal topologies, for example GaN HEMTs, and vertical topologies, for example HEMTs based on GaN-on-GaN, SiC, or Ga₂O₃.

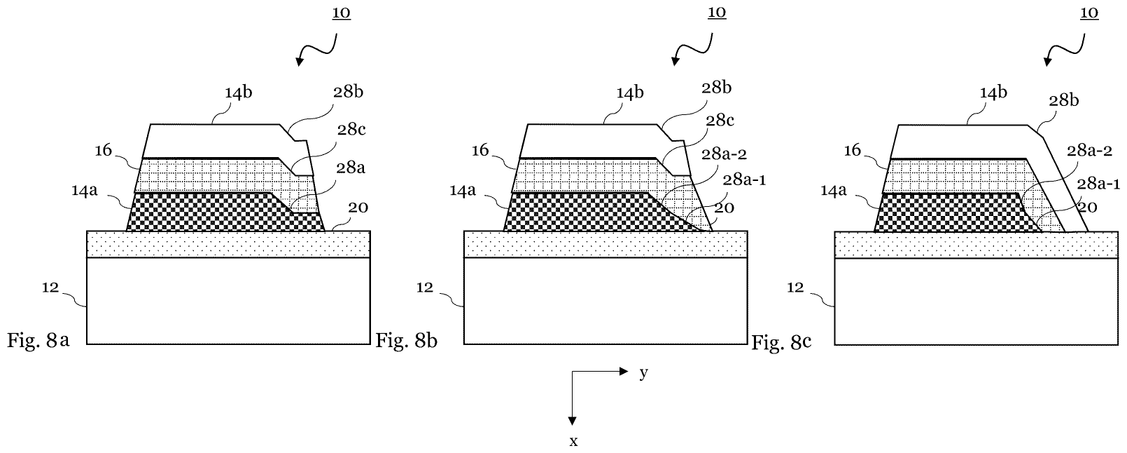

In the exemplary embodiments shown in FIGS. 8a to 8c, the first region 14a of the first conductivity type and the second region 14b of the second conductivity type are arranged in a semi-vertical configuration. In the semi-vertical configuration, the second region 14b of the second conductivity type may be formed above the first region 14a, where the first region 14a may include one or more recessed sections. Additionally or alternatively, the second region 14b may include one or more recessed sections. Additionally or alternatively, the semiconductor device 10 may include the intermediate region 16 of the third conductivity type arranged between the first region 14a and the second region 14b, and the intermediate region 16 may include one or more recessed sections or may not be recessed.

In the exemplary embodiments shown in FIGS. 8a to 8c, upon forming the first region 14a, one or more sections of it can be etched. Thus, at least a slope 28a may be formed between the at least one etched (recessed) section of the first region 14a and the section of the first region 14a that is not etched. Accordingly, by etching one or more sections of the second region 14b, at least a slope 28b may be formed between the recessed section of the second region 14b and the section of the second region 14b that is not etched. Additionally or alternatively, by etching a part of the intermediate region 16, at least a third slope 28c may be formed between the recessed and non-recessed sections of the intermediate region 16.

Thereby, the first shape of the first region 14a and the second shape of the second region 14 comprising a tip shape or a truncated tip shape or another polygon shape can be formed in order to achieve an efficient zapping process.

In the exemplary embodiment of FIG. 8a, the first region 14a, the second region 14b and the intermediate region 16 include one recessed section, and the slopes 28a, 28b and 28c, respectively, are formed. The slopes 28a, 28b and 28c can be the same or can be different from each other.

In the exemplary embodiment of FIG. 8b, the first region 14a includes two recessed sections, forming two slopes 28a-1 and 28a-2, whereas the second region 14b and the intermediate region 16 include one recessed section, forming the slopes 28b and 28c, respectively. Thereby, the first shape of the first region 14a and the second shape of the second region 14b are different from each other. The slopes 28a-1, 28a-2, 28b and 28c can be the same or can be different from each other.

In the exemplary embodiment of FIG. 8c, the first region 14a includes two recessed sections, forming two slopes 28a-1 and 28a-2, the second region 14b includes a recessed section, forming the slope 28b, and the intermediate region 16 is not recessed. Thereby, the first shape of the first region 14a and the second shape of the second region 14b are different from each other, and the intermediate region 16 may have a shape that can further enhance the zapping process. The slopes 28a-1, 28a-2 and 28b can be the same or can be different from each other.

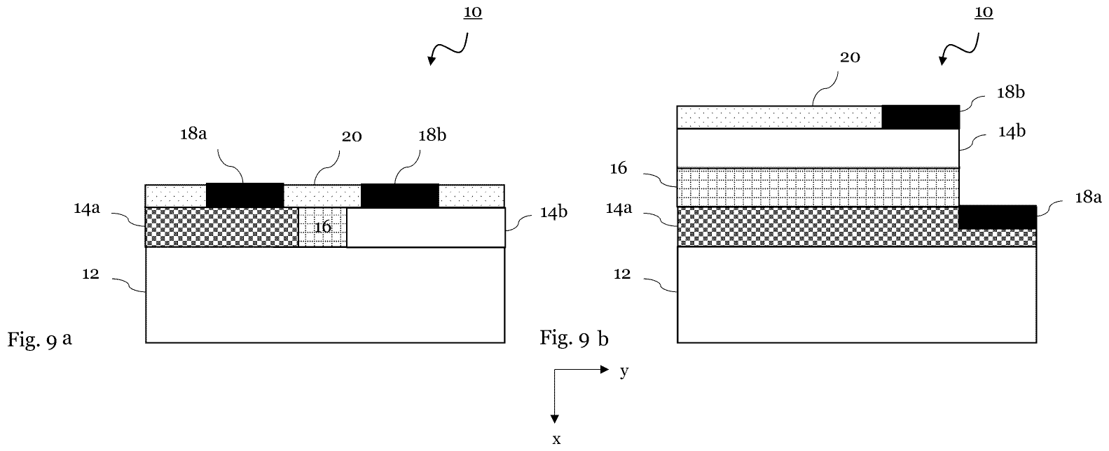

In the exemplary embodiment shown in FIG. 9a, the first region 14a and the second region 14b are arranged in a horizontal configuration with respect to their arrangement above the substrate 12, and the semiconductor layer 20 is arranged above the first region 14a and the second region 14b. In this embodiment, the first metallic gate 18a and the second metallic gate 18b contact the first region 14a and the second region 14b, respectively through the semiconductor layer 20. The semiconductor device 10 may also include the intermediate region 16 of the third conductivity type that is arranged between the first region 14a and the second region 14b.

The substrate 12 includes the first WBG semiconductor material, the first region 14a of the first conductivity type, the second region 14b of the second conductivity type and the intermediate region 16 of the third conductivity type include the second WBG semiconductor material, and the semiconductor layer 20 includes the third WBG semiconductor material, as described in the previous embodiments and examples.

The first metallic gate 18a may be partially or totally in contact with the first region 14a, or the first metallic gate 18a extends partially or totally inside the first region 14a. The second metallic gate 18b may be partially or totally in contact with the second region 14b, or the second metallic gate 18b extends partially or totally inside the second region 14b, as in the examples shown in FIGS. 5a to 5c or 6a to 6b. The first metallic gate 18a or the second metallic gate 18b may partially extend inside the intermediate region 16. The first metallic gate 18a and the second metallic gate 18b include the same materials as disclosed in the previous embodiments and examples.

In the exemplary embodiment shown in FIG. 9a, the semiconductor device 10 may further comprise an isolation implant in order to remove the 2DEG formed below the semiconductor layer 20, thereby avoiding an electrical short between the first region 14a and the second region 14b.

In the exemplary embodiment shown in FIG. 9b, the first region 14a of the first conductivity type and the second region 14b of the second conductivity type are arranged in the full vertical configuration above the substrate 12, where the second region 14b is arranged above the first region 14a, and the semiconductor layer 20 is arranged above the second region 14b. Optionally, the first region 14a and the second region 14b of the second conductivity type may be arranged in the semi-vertical configuration.

In the exemplary embodiment shown in FIG. 9b, the first metallic gate 18a in electrical contact with the first region 14a, and the second metallic gate contacts the second region 14b through the semiconductor layer 20. The semiconductor device 10 may comprise the intermediate region 16 with the third conductivity type arranged between the first region 14a and the second region 14b.

The substrate 12 includes the first WBG semiconductor material, the first region 14a of the first conductivity type, the second region 14b of the second conductivity type and the intermediate region 16 of the third conductivity type include the second WBG semiconductor material, and the semiconductor layer 20 includes the third WBG semiconductor material, as described in the previous embodiments and examples.

The first metallic gate 18a may be partially or totally in contact with the first region 14a, or the first metallic gate 18a may extend partially or totally inside the first region 14a. The second metallic gate 18b may be partially or totally in contact with the second region 14b, or the second metallic gate 18b mat extend partially or totally inside the second region 14b, as in the examples shown in FIGS. 5a to 5c or 6a to 6b. The first metallic gate 18a or the second metallic gate 18b may partially extend inside the intermediate region 16. The first metallic gate 18a and the second metallic gate 18b include the same materials as disclosed in the previous embodiments and examples.

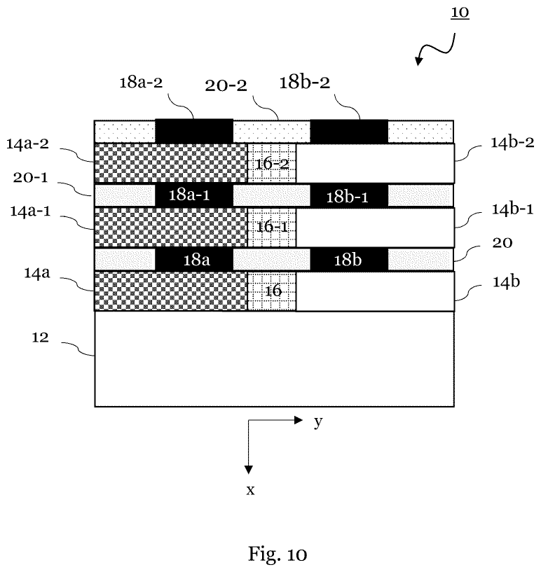

In the exemplary embodiment shown in FIG. 10, the first region 14a of the first conductivity type and the second region 14b of the second conductivity type are arranged in a horizontal configuration with respect to their arrangement above the substrate 12. The semiconductor device 10 may include the intermediate region 16 of the third conductivity type arranged between the first region 14a and the second region 14b. The semiconductor device 10 further includes the semiconductor layer 20 arranged above the first region 14a and the second region 14b, and the first metallic gate 18a and the second metallic gate 18b contact the first region 14a and the second region 14b, respectively through the semiconductor layer 20.

The substrate 12 includes the first WBG semiconductor material, the first region 14a of the first conductivity type, the second region 14b of the second conductivity type and the intermediate region 16 of the third conductivity type includes the second WBG semiconductor material, and the semiconductor layer 20 includes the third WBG semiconductor material, as described in the previous embodiments and examples.

The first metallic gate 18a may be partially or totally in contact with the first region 14a, or the first metallic gate 18a extends partially or totally inside the first region 14a. The second metallic gate 18b may be partially or totally in contact with the second region 14b, or the second metallic gate 18b extends partially or totally inside the second region 14b, as in the examples shown in FIGS. 5a to 5c or 6a to 6b. The first metallic gate 18a or the second metallic gate 18b may partially extend inside the intermediate region 16. The first metallic gate 18a and the second metallic gate 18b include the same materials as disclosed in the previous embodiments and examples.

In the exemplary embodiment shown in FIG. 10, the semiconductor device 10 further includes at least one additional first region 14a-1, 14a-2 of the first conductivity type and at least one additional second region 14b-1, 14b-2 of the second conductivity type that are arranged above the semiconductor layer 20. The semiconductor device 10 further includes at least one additional first metallic gate 18b-1, 18b-2 in electrical contact with the at least one additional first region 14a-1, 14a-2, respectively, and at least one additional second metallic gate 18b-1,18b-2 in electrical contact with the at least one additional second region 14b-1, 14b-2, respectively. Further, the semiconductor device 10 includes at least one additional semiconductor layer 20-1, 20-2 that is arranged above the at least one additional first region 14a-1, 14a-2 and the at least one additional second region 14b-1, 14b-2, respectively.

The at least one additional first metallic gate 18a-1, 18a-2 and the at least one additional second metallic gate 18b-1, 18b-2 contact the at least one additional first region 14a-1, 14a-2 and the at least one additional second region 14b-1, 14b-2 through the at least one additional semiconductor layer 20-1, 20-2, respectively.

The at least one additional first region 14a-1, 14b-2 of the first conductivity type and the at least one additional second region 14b-1, 14b-2 of the first conductivity type include the second WBG semiconductor material, and the at least one additional semiconductor layer 20-1, 20-2 includes the third WBG semiconductor material, as described in the previous embodiments and examples.

In the exemplary embodiment shown in FIG. 10, the at least one additional first region 14a-1 and the at least one additional second region 14b-1 form at least one additional Zener PN diode configured as an anti-fuse. Respectively, another additional first region 14b-1 and another additional second region 14b-2 form another additional Zener PN diode configured as an anti-fuse.

The semiconductor device 10 may further include at least one additional intermediate region 16-1, 16-2 of the third conductivity type arranged between the at least one additional first region 14a-1, 14a-2 of the first conductivity type and the at least one additional second region 14b-1, 14b-2 of the first conductivity type. The at least one additional intermediate region 16-1, 16b-2 of the third conductivity type includes the second WBG semiconductor material.

The at least one additional first metallic gate 18a-1, 18a-2 may be partially or totally in contact with the at least one additional first region 14a-1, 14a-2, respectively, or the first metallic gate 18a-1, 18a-2 may extend partially or totally inside the at least one additional first region 14a-1, 14a-2. The second metallic gate 18b-1, 18b-2 may be partially or totally in contact with the at least one additional second region 14b-1, 14b-2, respectively, or the second metallic gate 18b-1, 18b-2 may extend partially or totally inside the at least one additional first region 14b-1, 14b-2, respectively, as in the examples shown in FIGS. 5a to 5c or 6a to 6b. The at least one additional first metallic gate 18a-1, 18a-2 or the at least one additional second metallic gate 18b-1, 18b-2 may partially extend inside the at least one additional intermediate region 16-1, 16-2, respectively. The at least one additional first metallic gate 18a-1, 18a-2 and the at least one additional second metallic gate 18b-1, 18b-2 may include the same materials as disclosed in the previous embodiments and examples.

The exemplary embodiment shown in FIG. 10 enables creation of a multi-stack of anti-fuses where multiple levels can be created between the semiconductor layer 20 and the at least one additional semiconductor layer 20-1, and between an additional semiconductor layer 20-1 and another additional semiconductor layer 20-2.

In the exemplary embodiment shown in FIG. 10, the semiconductor device 10 may further include a network of metal interconnections, for example vias or plugs, contacting the first region 14a and the at least one additional first region 14a-1, and contacting the first region 14b and the at least one additional second region 14b-1. Similarly, when further additional first regions are formed, the network of metal interconnections may further contact an additional first region 14a-1 and another additional second region 14a-2, and may further contact an additional second region 14b-land another additional second region 14b-2.

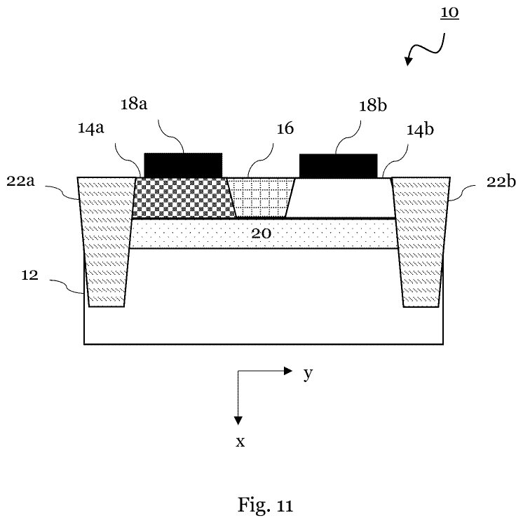

In an embodiment, shown in FIG. 11, the semiconductor device 10 further includes at least one structure 22a, 22b of a thermal insulation material that is partially or fully in contact with the first region 14a and/or the second region 14b and/or the substrate 12. The at least one structure 22a, 22b of thermal insulation material includes SiO₂, or a nitride compound comprising any one of Si₃N₄ or AlGaN or AlN.

Additionally or alternatively, the at least one structure 22a, 22b of the thermal insulation material may be partially or fully in contact with the semiconductor layer 20. Alternatively, the at least one structure 22a, 22b of a thermal insulation material may be partially or fully in contact with the substrate 12 and/or the semiconductor layer 20. Alternatively, the at least one structure 22a, 22b of a thermal insulation material may not contact the first region 14a and/or the second region 14b.

Notably, the exemplary embodiment shown in FIG. 11 may cause a thermal enhancement, e.g., overheating, during a zapping process that may facilitate the programming of the anti-fuse.

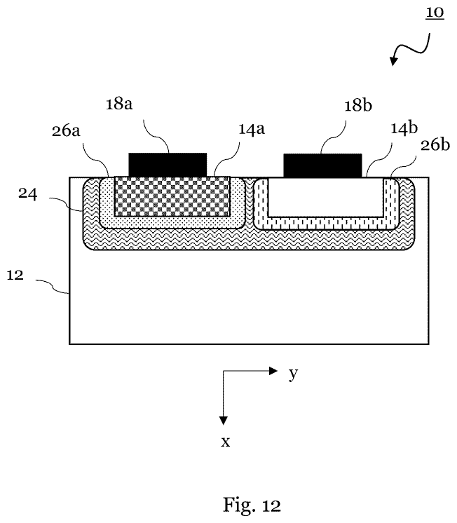

FIG. 12 shows a schematic diagram of a semiconductor device 10 according to another exemplary embodiment. In the exemplary embodiment shown in FIG. 12, the first region 14a of the first conductivity type and the second region 14b of the second conductivity type are arranged in an N-well structure 24 or a P-well structure 24 formed in the substrate 12. Alternatively, the first region 14a is arranged in a first well structure 26a and the second region 14b is arranged in a second well structure 26b, where the first well structure 26a and the second well structure 26b include an N-well structure or a P-well structure formed in the substrate 12.

Additionally or alternatively, the first region 14a is arranged in the first well structure 26a and the second region 14b is arranged in the second well structure 26b, where the first well structure 26a and the second well structure 26b include an N-well structure or a P-well structure that are arranged in the N-well or P-well structure 24 formed in the substrate 12.

The N-well or P-well structure 24, the first well structure 26a and the second well structure 26b may be formed by implantation. Alternatively, N-well or P-well structure 24, the first well structure 26a and the second well structure 26b may be formed by etch and epitaxial regrowth.

In the exemplary embodiment shown in FIG. 12, the substrate 12 may include the first WBG semiconductor material or an UWBG semiconductor material. The first WBG semiconductor material and the UWBG semiconductor material may include, for example, GaN, SiC, Ga₂O₃. The first WBG semiconductor material or the UWBG semiconductor material may include a heteroepitaxial bulk material, including GaN on Si, or GaN on SiC, or GaN on diamond, or a WBG semiconductor material semiconductor on insulator material, or an UWBG semiconductor material on insulator material.

In the present disclosure, an UWBG semiconductor material includes a semiconductor material with a bandgap above 4 eV.

In the exemplary embodiment shown in FIG. 12, the first region 14a of the first conductivity type, the second region 14b of the second conductivity type and the intermediate region 16 of the third conductivity type may include the second WBG semiconductor material or an UWBG semiconductor material. The first WBG semiconductor material and the UWBG semiconductor material may include GaN, SiC or Ga₂O₃. For example, the band gap value of Ga₂O₃ is 4.8 eV.

The chemical species used for doping the first region 14a and the second region 14b may be for example, but not as a limitation, magnesium, iron or silicon when the second WBG semiconductor material includes GaN. Alternatively, when the second WBG semiconductor material includes SiC, the dopants can be, for example, phosphorous, boron, aluminum, or nitrogen. Alternatively, when the second WBG semiconductor material includes Ga₂O₃, the dopants can be, for example, Si, tin, germanium, nitrogen, magnesium or iron.

The semiconductor device 10 may further include the semiconductor layer 20 including the third WBG semiconductor material, as described in the previous embodiments and examples.

In this embodiment, the semiconductor device 10 may further include the first metallic gate 18a in electrical contact with the first region 14a, and the second metallic gate 18b in electrical contact with the second region 14b.

The first metallic gate 18a may be partially or totally in contact with the first region 14a, or the first metallic gate 18a extends partially or totally inside the first region 14a. The second metallic gate 18b may be partially or totally in contact with the second region 14b, or the second metallic gate 18b extends partially or totally inside the second region 14b, as in the examples shown in FIGS. 5a to 5c or 6a to 6b. The first metallic gate 18a or the second metallic gate 18b may partially extend inside the intermediate region 16. The first metallic gate 18a and the second metallic gate 18b include the same materials as disclosed in the previous embodiments and examples.

The semiconductor device 10 may further include at least one structure 22a, 22b of a thermal insulation material partially or fully in contact with the first region 14a and/or the second region 14b and/or the substrate 12. The at least one structure 22a, 22b of thermal insulation material may include silicon dioxide, SiO₂, or a nitride compound including any one of Si₃N₄, or AlGaN, or AlN.

Additionally or alternatively, the at least one structure 22a, 22b of a thermal insulation material may be partially or fully in contact with the semiconductor layer 20. Alternatively, the at least one structure 22a, 22b of a thermal insulation material may be partially or fully in contact with the substrate 12 and/or the semiconductor layer 20. Alternatively, the at least one structure 22a, 22b of a thermal insulation material may not contact the first region 14a and/or the second region 14b.

Notably, the semiconductor device 10 of the embodiment shown in FIG. 12 may be used in general WBG and UWBG technologies; thus, standard fabrication techniques of WBG and UWBG technologies may be used to fabricate the semiconductor device 10.

The semiconductor device 10 according to the exemplary embodiments of this disclosure provides several advantages:
It enables a cost-free solution to implement Zener PN diodes configured as anti-fuses in WBG power semiconductor technologies.
It allows to perform trimming in WBG technologies (only available nowadays in silicon technology).
It allows tuning for voltage reference circuits in WBG (largely used in Integrated Circuit Designs).
It allows the implementation of serial code identification for dies/chips in WBG devices.
It provides Zener PN diodes configured as anti-fuses that are “one time programmable,” since no reconfiguration is required every time a power supply is interrupted, applied or disconnected.
It is less susceptible to alpha particles.

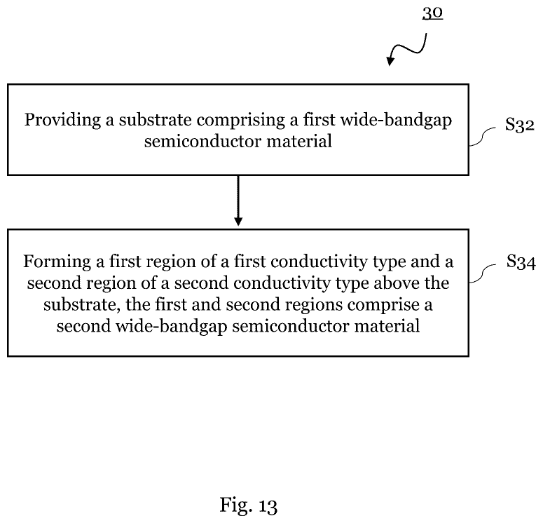

FIG. 13 shows steps of a method 30 for producing a semiconductor device according to an exemplary embodiment of the present disclosure.

In a first step, S32, the substrate 12 is provided. The substrate 12 includes a first WBG semiconductor material, including SiC or Ga₂O₃. Alternatively, the first WBG semiconductor material includes a heteroepitaxial bulk material, including GaN on Si, or GaN on SiC, or GaN on diamond, or a WBG semiconductor on insulator material. The substrate 12 may include a base structure with one or more layers on top formed by an epitaxial growth process.

In a second step, S34, a first region 14a of a first conductivity type and a second region 14b of a second conductivity type arranged above the substrate 12 are formed. The first region 14a and the second region 14b include a second WBG semiconductor material. For example, the second WBG semiconductor material includes GaN.

The first region 14a of a first conductivity type may be a P-type region or an N-type region. Conversely, the second region 14b of a second conductivity type may be an N-type region or a P-type region. Thus, the first region 14a and the second region 14b form a Zener PN diode configured as an anti-fuse.

In general, the semiconductor device 10 can be manufactured by standard mask/implant processes, controlled successive epitaxial growths and successive epitaxy and etching techniques.

The method 30 may further include forming an intermediate region 16 of a third conductivity type that may be arranged between the first region 14a and the second region 14b. The intermediate region 16 may include the second WBG semiconductor material, and may be a P-type region or an N-type region or an undoped-type region.

The first region 14a and the second region 14b may be arranged in a horizontal configuration with respect to their arrangement above the substrate 12, where the first region 14a may be arranged above the substrate 12 and the second region 14b may be arranged above the substrate 12 and next to the first region 14a.

Alternatively, the first region 14a and the second region 14b may be arranged in a vertical configuration with respect to their arrangement above the substrate 12.

The vertical configuration may include a full vertical configuration or a semi-vertical configuration.

In the full vertical configuration, the second region 14b may be arranged above the first region 14a and the first region 14a may be arranged above the substrate 12.

In the semi-vertical configuration, the second region 14b of the second conductivity type may be formed above the first region 14a, where the first region 14a may include one or more recessed sections. Additionally or alternatively, the second region 14b may include one or more recessed sections. Additionally or alternatively, the semiconductor device 10 may include the intermediate region 16 of the third conductivity type arranged between the first region 14a and the second region 14b, and the intermediate region 16 may include one or more recessed sections or may not be recessed.

The first region 14a and the second region 14b may be separated by a distance, or the first region 14a and the second region 14b may be contiguous, or the first region 14a and the second region 14b may be partially overlapping.

The first region 14a may have a first shape, the first shape may include a first lateral protrusion, the first lateral protrusion may have a tip shape or a truncated tip shape or another polygon shape, or the first shape may include a cylindrical shape or a cylindrical shape with a first lateral protrusion, where the first lateral protrusion may have a tip shape or a truncated tip shape or another polygon shape. The second region 14b may have a second shape, the second shape may include a second lateral protrusion, the second lateral protrusion may have a tip shape or a truncated tip shape or another polygon shape, or the second shape may include a cylindrical shape or a cylindrical shape with a second lateral protrusion, where the lateral protrusion may have a tip shape or a truncated tip shape or another polygon shape.

The method 30 may further include forming a semiconductor layer 20 that may include a third WBG semiconductor material, and may be arranged between the substrate 12 and the first region 14a and the second region 14b, respectively. For example, the third WBG semiconductor material may include AlGaN.

The method 30 may further include forming the semiconductor layer 20, including the third WBG semiconductor material, where the semiconductor layer 20 may be arranged above the first region 14a and the second region 14b. Alternatively, the second region 14b may be arranged above the first region 14a, and the semiconductor layer 20 may be arranged above the second region 14b.

The method 30 may further include forming a first metallic gate 18a in electrical contact with the first region 14a, and a second metallic gate 18b in electrical contact with the second region 14b.

The first metallic gate 18a and the second metallic gate 18b may contact the first region 14a and the second region 14b through the semiconductor layer 20. Alternatively, the second metallic gate 18b may contact the second region 14b through the semiconductor layer 20.

The first metallic gate 18a may be partially or totally in contact with the first region 14a or the first metallic gate 18a may extend partially or totally inside the first region 14a. The second metallic gate 18b may be partially or totally in contact with the second region 14b or the second metallic gate 18b may extend partially or totally inside the second region 14b.

The first metallic gate 18a and the second metallic gate 18b may include aluminum, titanium, copper, gold or another metallic element, or a metal stack including any one of Ni/Au, Ni/Ag, Pd/Au, Cr/Au, Pt/Au, Ti/Pt/Au, Ni/Si, W/Si, Ti/Al, Ti/Al/Ti, or TIN/Al/TiN. However, other suitable material combinations may also be possible.

The method 30 may further include: forming at least one additional first region 14a-1, 14a-2 of the first conductivity type and at least one additional second region 14b-1, 14b-2 of the second conductivity type that may be arranged above the semiconductor layer 20; forming at least one additional first metallic gate 18a-1, 18a-2 in electrical contact with the at least one additional first region 14a-1, 14a-2 and at least one additional second metallic gate 18b-1, 18b-2 in electrical contact with the at least one additional second region 14b-1, 14b-2; and forming at least one additional semiconductor layer 20-1, 20-2 that may be arranged above the at least one additional first region 14a-1, 14a-2 and the at least one additional second region 14b-1, 14b-2.

The at least one additional first metallic gate 18a-1, 18a-2 and the at least one additional second metallic gate 18b-1, 18b-2 may contact the at least one additional first region 14a-1, 14a-2 and the at least one additional second region 14b-1, 14b-2 through the at least one additional semiconductor layer 20-1, 20-2.

The at least one additional first region 14a-1, 14a-2 and the at least one additional second region 14b-1, 14b-2 may include the second wide-bandgap semiconductor material, whereas the at least one additional semiconductor layer 20-1, 20-2 may include the third wide-bandgap semiconductor material.

Further, the at least one additional first region 14a-1, 14a-2 and the at least one additional second region 14b-1, 14b-2 form at least one additional Zener PN diode configured as an anti-fuse.

The method may further include forming the first region 14a and the second region 14b that may be arranged in an N-well structure 24 or a P-well structure 24 formed in the substrate 12. Alternatively, the first region 14a may be arranged in a first well structure 26a and the second region 14b is arranged in a second well structure 26b, where the first well structure 26a and the second well structure 26a may include an N-well structure or a P-well structure formed in the substrate 12.

The method 30 may further include forming at least one structure 22a, 22b of a thermal insulation material that may be partially or fully in contact with the first region 14a and/or the second region 14b and/or the substrate 12. The at least one structure 22a, 22b of thermal insulation material may include SiO₂ or a nitride compound including any one of Si₃N₄, or AlGaN, or AlN.

Examples of fabrication techniques that may be used to form the first region 14a of the first conductivity type and the first shape, the second region 14b of the second conductivity type and the second shape, the intermediate region 16 of the third conductivity type, the first metallic gate 18a and the second metallic gate 18b are the same as those disclosed above in the different embodiments and examples of the semiconductor device 10.

The present disclosure has been described in conjunction with various embodiments as examples as well as implementations. However, other variations can be understood and effected by those persons skilled in the art and practicing the claimed matter, from the studies of the drawings, this disclosure and the independent claims. In the claims as well as in the description the word “comprising” does not exclude other elements or steps and the indefinite article “a” or “an” does not exclude a plurality. A single element or other unit may fulfill the functions of several entities or items recited in the claims. The mere fact that certain measures are recited in the mutual different dependent claims does not indicate that a combination of these measures cannot be used in an advantageous implementation.

What is claimed is:

1. A semiconductor device, the semiconductor device comprising:
a substrate comprising a first wide-bandgap semiconductor material; and
a first region of a first conductivity type and a second region of a second conductivity type arranged above the substrate,
wherein the first region and the second region comprise a second wide-bandgap semiconductor material, and
wherein the first region and the second region form a Zener PN diode configured as an anti-fuse.

2. The semiconductor device according to claim 1,
wherein the first region and the second region are arranged in a horizontal configuration with respect to their arrangement above the substrate, wherein the first region is arranged above the substrate and the second region is arranged above the substrate and next to the first region, or
wherein the first region and the second region are arranged in a vertical configuration with respect to their arrangement above the substrate, wherein the second region is arranged above the first region and the first region is arranged above the substrate.

3. The semiconductor device according to claims 1,
wherein the first region and the second region are separated by a distance, or the first region and the second region are contiguous, or the first region and the second region are partially overlapping.

4. The semiconductor device according to claim 1,
wherein the first region has a first shape, the first shape comprising a first lateral protrusion, the first lateral protrusion having a tip shape or a truncated tip shape or another polygon shape, or the first shape comprises a cylindrical shape or a cylindrical shape with a first lateral protrusion, wherein the first lateral protrusion has a tip shape or a truncated tip shape or another polygon shape, and
wherein the second region has a second shape, the second shape comprising a second lateral protrusion, the second lateral protrusion having a tip shape or a truncated tip shape or another polygon shape, or the second shape comprises a cylindrical shape or a cylindrical shape with a second lateral protrusion, wherein the second lateral protrusion has a tip shape or a truncated tip shape or another polygon shape.

5. The semiconductor device according to claim 1,
wherein the semiconductor device further comprises a first metallic gate in electrical contact with the first region, and a second metallic gate in electrical contact with the second region.

6. The semiconductor device according to claim 1,
wherein the semiconductor device further comprises a semiconductor layer comprising a third wide-bandgap semiconductor material that is arranged between the substrate and the first region and the second region, respectively.

7. The semiconductor device according to claim 1,
wherein the semiconductor device further comprises a semiconductor layer comprising a third wide-bandgap semiconductor material, and
wherein:
the semiconductor layer is arranged above the first region and the second region; or
the second region is arranged above the first region, and the semiconductor layer is arranged above the second region.

8. The semiconductor device according to claim 5,
wherein the semiconductor device further comprises a semiconductor layer, and
wherein:
the first metallic gate and the second metallic gate contact the first region and the second region through the semiconductor layer, or
wherein the second metallic gate contacts the second region through the semiconductor layer.

9. The semiconductor device according to claim 8,
wherein the semiconductor device further comprises:
at least one additional first region of the first conductivity type and at least one additional second region of the second conductivity type that are arranged above the semiconductor layer, wherein the at least one additional first region and the at least one additional second region comprise the second wide-bandgap semiconductor material;
at least one additional first metallic gate in electrical contact with the at least one additional first region and at least one additional second metallic gate in electrical contact with the at least one additional second region; and
at least one additional semiconductor layer comprising a third wide-bandgap semiconductor material and arranged above the at least one additional first region and the at least one additional second region,
wherein the at least one additional first metallic gate and the at least one additional second metallic gate contact the at least one additional first region and the at least one additional second region through the at least one additional semiconductor layer; and
wherein the at least one additional first region and the at least one additional second region form at least one additional Zener PN diode configured as the anti-fuse.

10. The semiconductor device according to claim 1,
wherein the first region and the second region are arranged in an N-well structure or a P-well structure formed in the substrate; or
wherein the first region is arranged in a first well structure and the second region is arranged in a second well structure, wherein the first well structure and the second well structure comprise an N-well structure or a P-well structure formed in the substrate.

11. The semiconductor device according to claim 1,
wherein the semiconductor device further comprises at least one structure of a thermal insulation material that is partially or fully in contact with the first region and/or the second region and/or the substrate, wherein the at least one structure of thermal insulation material comprises silicon dioxide (SiO₂), or a nitride compound comprising any one of silicon nitride (Si₃N₄), or aluminum gallium nitride (AlGaN), or aluminum nitride (AlN).

12. The semiconductor device according to claim 1,
wherein the semiconductor device further comprises an intermediate region of a third conductivity type that is arranged between the first region and the second region, wherein the intermediate region comprises the second wide-bandgap semiconductor material, and wherein the intermediate region is a P-type region or an N-type region or an undoped-type region.

13. The semiconductor device according to claim 1,
wherein the second wide-bandgap semiconductor material comprises gallium nitride (GaN).

14. The semiconductor device according to claim 6,
wherein the third wide-bandgap semiconductor material comprises aluminum gallium nitride (AlGaN).

15. The semiconductor device according to claim 5,
wherein the first metallic gate is partially or totally in contact with the first region or the first metallic gate extends partially or totally inside the first region, and
wherein the second metallic gate is partially or totally in contact with the second region or the second metallic gate extends partially or totally inside the second region.

16. The semiconductor device according to claim 5,
wherein the first metallic gate and the second metallic gate comprise aluminum, titanium, copper, gold or another metallic element, or a metal stack comprising any one of nickel/gold (Ni/Au), nickel/silver (Ni/Ag), Palladium/gold (Pd/Au), Chromium/gold (Cr/Au), Platinum/gold (Pt/Au), Titanium/Platinum/gold (Ti/Pt/Au), nickel/silicone (Ni/Si), Tungsten/silicone (W/Si), Titanium/Aluminum (Ti/Al), Titanium/Aluminum/Titanium (Ti/Al/Ti), or Titanium nitride/Aluminum/Titanium nitride (TiN/Al/TiN).

17. The device according to claim 1,
wherein the first wide-bandgap semiconductor material comprises silicon carbide (SiC) or gallium oxide (Ga₂O₃), or
wherein the first wide-bandgap semiconductor material comprises a hetroepitaxial bulk material, wherein the hetroepitaxial bulk material comprises gallium nitride (GaN) on silicon (Si), or GaN on silicon carbide (SiC), or GaN on diamond, or a wide-bandgap semiconductor on insulator material.

18. A method for producing a semiconductor device, the method comprising:
providing a substrate comprising a first wide-bandgap semiconductor material; and
forming a first region of a first conductivity type and a second region of a second conductivity type arranged above the substrate, wherein the first region and the second region comprise a second wide-bandgap semiconductor material,
wherein the first region and the second region form a Zener PN diode configured as an anti-fuse.
